(19) United States
(12) Patent Application Publication
(10) Pub. No.: US 2023/0125859 A1
(43) Pub. Date: Apr. 27, 2023

(54) METHOD OF MANUFACTURING A SEMICONDUCTOR DEVICE INCLUDING ION IMPLANTATION AND SEMICONDUCTOR DEVICE

(71) Applicant: Infineon Technologies AG, Neubiberg (DE)

(72) Inventors: Daniel Schlögl, Villach (AT); Hans-Joachim Schulze, Taufkirchen (DE); Moriz Jelinek, Villach (AT); Francisco Javier Santos Rodriguez, Villach (AT)

(21) Appl. No.: 17/974,592

(22) Filed: Oct. 27, 2022

(30) Foreign Application Priority Data
Oct. 27, 2021 (DE) 102021127927.5

(51) Int. Cl. H01L 21/265; H01L 29/06; H01L 21/324

(52) U.S. Cl. CPC H01L 21/265; H01L 29/0603; H01L 21/324

(57) ABSTRACT

A method of manufacturing a semiconductor device in a semiconductor body having a first surface and a second surface is proposed. The method includes implanting protons through the second surface into the semiconductor body. The method further includes implanting ions through the second surface into the semiconductor body. The ions are ions of a non-doping element having an atomic number of at least 9. Thereafter, the method further includes processing the semiconductor body by thermal annealing.

### TECHNICAL FIELD

The present disclosure is related to a method of manufacturing a semiconductor device, in particular to a method of manufacturing a semiconductor device including ion implantation.

### BACKGROUND

Technology development of new generations of semiconductor devices, e.g. diodes or insulated gate field effect transistors (IGFETs) such as metal oxide semiconductor field effect transistors (MOSFETs) or insulated gate bipolar transistors (IGBTs), aims at improving electric device characteristics and reducing costs by shrinking device geometries. Although costs may be reduced by shrinking device geometries, a variety of tradeoffs and challenges have to be met when increasing device functionalities per unit area. For example, a thickness reduction of the semiconductor body may be beneficial with respect to reduction of static and dynamic electric losses. Thickness reduction, however, typically comes at the cost of e.g. breakdown voltage and cosmic ray performance. Semiconductor devices may therefore include a field stop region for providing sufficient softness during electric switching. The field stop region aims at protecting a certain amount of charge carrier plasma so that these charges can carry the load current during an end of reverse recovery.

There is a need for improving electric characteristics of semiconductor devices.

### SUMMARY

An example of the present disclosure relates to a method of manufacturing a semiconductor device in a semiconductor body having a first surface and a second surface. The method includes implanting protons through the second surface into the semiconductor body. The method further includes implanting ions through the second surface into the semiconductor body. The ions are ions of a non-doping element having an atomic number of at least 9, or even at least 18. Thereafter, the method further includes processing the semiconductor body by thermal annealing.

An example of the present disclosure relates to a method of manufacturing a semiconductor device in a semiconductor body having a first surface and a second surface. The method includes introducing hydrogen through the second surface into the semiconductor body. The method further includes implanting ions through the second surface into the semiconductor body. The ions are ions of a non-doping element having an atomic number of at least 9. Thereafter, the method further includes processing the semiconductor body by thermal annealing.

Another example of the present disclosure relates to a semiconductor device. The semiconductor device includes an n-doped region defined by hydrogen-related donors in a silicon semiconductor body. The semiconductor device further includes non-doping elements having an atomic number of at least 9. A vertical distance between a peak in a vertical charge carrier concentration profile in the n-doped region and a peak in a vertical concentration profile of the non-doping elements is smaller than 50% of a vertical distance between the peak in the vertical concentration profile of the non-doping elements and a closest surface of the silicon semiconductor body.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of a semiconductor device and a method of manufacturing a semiconductor device and together with the description serve to explain principles of the embodiments. Further embodiments are described in the following detailed description and the claims.

FIGS. 1A to 1C and FIG. 2 are schematic cross-sectional views for illustrating process features of manufacturing a semiconductor device.

FIG. 3 is a schematic cross-sectional view of a semiconductor device that may be manufactured by the process features of FIGS. 1A to 1C and FIG. 2.

FIGS. 4 and 5 are schematic graphs for illustrating experimental results of concentration profiles.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate

An example of a method of manufacturing a semiconductor device in a semiconductor body having a first surface and a second surface may include implanting protons through the second surface into the semiconductor body. The method may further include implanting ions through the second surface into the semiconductor body. The ions are ions of a non-doping element having an atomic number of at least 9. Thereafter, the method may further include processing the semiconductor body by thermal annealing.

The semiconductor device may be an integrated circuit, or a discrete semiconductor device or a semiconductor module, for example. The semiconductor device may be or include a power semiconductor device, e.g. a vertical power semiconductor device having a load current flow between a first surface and a second surface. The semiconductor device may be or may include a power semiconductor diode, or a power semiconductor IGBT (insulated gate bipolar transistor), or a reverse conducting (RC) IGBT or a power semiconductor transistor such as a power semiconductor IGFET (insulated gate field effect transistor, e.g. a metal oxide semiconductor field effect transistor). The power semiconductor device may be configured to conduct currents of more than 1A or more than 10 A or even more than 30 A and may be further configured to block voltages between load terminals, e.g. between emitter and collector of an IGBT, or between cathode and anode of a diode, or between drain and source of a MOSFET in the range of several hundreds of up to several thousands of volts, e.g. 400 V, 650V, 1.2 kV, 1.7 kV, 3.3 kV, 4.5 kV, 5.5 kV, 6 kV, 6.5 kV. The blocking voltage may correspond to a voltage class specified in a datasheet of the power semiconductor device, for example.

The semiconductor body may include or consist of a semiconductor material from the group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). For example, the semiconductor body may be a magnetic Czochralski, MCZ, or a float zone (FZ) or an epitaxially deposited silicon semiconductor body.

For example, the protons may be implanted by one or more proton implantation processes that may differ from one another by at least one of a proton implantation dose, a proton implantation energy, or a proton implantation tilt angle. For example, by increasing the proton implantation energy, an end of range peak of the protons or a penetration depth of the protons may be increased. The penetration depth may be a vertical distance from the surface where the concentration of an implanted element is smaller than two orders of magnitude, or three orders of magnitude, or four orders of magnitude than a peak concentration of an end of range peak of the implanted element, for example. Multiple proton implantations may allow for shaping doping profiles, e.g. profiles of hydrogen-related donors, by overlapping profiles of different proton implantation processes.

The ions of a non-doping element having an atomic number of at least 9, or even at least 18 may also be implanted by one or more ion implantation processes that may differ from by at least one of a ion implantation dose, an ion implantation energy, or an ion implantation tilt angle. For example, by increasing the ion implantation energy, an end of range peak of the ions or a penetration depth of the ions may be increased.

For example, the non-doping element may be an element that is not configured to be activated as a dopant for altering the number of majority or minority carriers in the semiconductor body. Different from a non-doping element, a doping element may be an element that is configured to be activated as a dopant for altering the number of majority or minority carriers in the semiconductor body. For example, the doping element may be a shallow-level donor or acceptor, or may be a deep-level donor or acceptor.

By combining the proton implantation with the implantation of ions of a non-doping element having an atomic number of at least 9, or even at least 18 additional vacancies may be generated for achieving targeted vacancy concentrations required to increase the doping efficiency of proton irradiation. The size of the ions of a non-doping element having an atomic number of at least 9 atoms substantially exceeds the size of protons or helium ions. In this way, the energy and dose of these ion implantation(s) of a non-doping element having an atomic number of at least 9 may allow for a high flexibility in setting the resulting proton-induced donor profiles while at the same time greatly reducing the total dose required to achieve these profiles and the resulting targeted integral dose of the n-doped region, e.g. n-type field stop dose. Furthermore, the method may also allow for exceeding an otherwise observed maximum concentration of hydrogen-related donors.

For example, an ion having an atomic number of at least 9, or even at least 18 that is to be implanted and is suitable for vacancy generation by having a sufficient size is, inter alia, argon, Ar, which allows for a very high concentration of vacancies even at relatively low implantation doses and, moreover, is a common implantation atom in power semiconductor manufacturing. Of course, ions of other non-doping elements that are significantly larger compared to hydrogen, such as silicon, krypton, xenon, neon, germanium, fluorine may also be used.

For example, the implantation energy for the implantation of the ions may be at least 20 keV, at least 30 keV or at least 50 keV. According to some embodiments, the implantation energy me be at least 100 keV. These examples are especially valid for argon as the non-doping species of the ions. An implantation angle for the implantation of the ions may, for example, be smaller than 8°, or even smaller than 1.5°.

For example, the implantation energy for the implantation of the protons may be at least 200 keV, or at least 300 keV. These examples may be combined in a beneficial way with the above-mentioned examples of the implantation energies for the ions, e. g. argon. The implantation of the protons may be carried out, for example, perpendicular to the surface of the semiconductor (implantation angle of 90°) or inclined (e.g. implantation angle of 60° or less).

For many proton-induced doping profiles, only one proton implantation and one or two further implantations of ions having an atomic number of at least 9 with a relatively low implantation dose may be required to set the desired profile shape with a high ratio of electrically active donors to the total implanted dose (e.g. protons plus argon). For field stop regions or zones requiring multiple doping peaks, even more argon (as an example of an ion having an atomic number of at least 9, or even at least 18)/proton implantations may be used.

The method described herein may not only lead to increased doping efficiency, but also enables doping profiles with a relatively small drop in the doping level in the vertical direction of the implanted wafer. This may be due to, in particular, the situation that the vacancies, which are generated to a large extent in the end of range by the irradiation with the ions having an atomic number of at least 9, may diffuse out both in depth and in the direction of the side through which the implantation was carried out, and can then in turn form the complexes effective as donors in the region affected by this vacancy diffusion in combination with the diffusing hydrogen atoms. Another benefit above is that smaller particles resting on the backside can be eliminated by irradiation with the ions having an atomic number of at least 9 and thus no longer interfere with the homogeneity of the generated n-doped region including hydrogen-related donors by avoiding masking effects induced by these particles.

For example, the thermal annealing may be carried out in a temperature range from 350° C. to 430° C., or from 360° C. to 410° C., or from 370° C. to 400° C. for a period from 30 minutes to 4 hours. For example, thermal annealing of the semiconductor body may be carried out by a furnace process or by rapid thermal processing, RTP. In addition or as an alternative, e.g. depending on a depth of the region that is to be annealed, annealing may be carried out by melt or non-melt laser thermal annealing, LTA.

For example, the semiconductor body may be a silicon semiconductor body and the ions, i.e. the ions of a non-doping element having an atomic number of at least 9, may include ions of silicon, argon, krypton, xenon, neon, germanium, fluorine.

For example, the ions of a non-doping element having an atomic number of at least 9 may be implanted at a dose smaller than 10¹³cm⁻². For example, the dose may range from 10¹¹ cm⁻² to 10¹³cm⁻², or from 5×10¹¹ cm⁻² to 5×10¹² cm⁻². The dose limitation may allow for avoiding formation of higher-order defect complexes that would not be annihilated by the thermal annealing described above and thus could undesirably lower the minority carrier lifetime. In contrast, at the implantation doses mentioned above, only vacancies and vacancy complexes may be formed, which may not have a critical recombination effect after the thermal annealing process, in particular after decoration with hydrogen.

For example, the method may further comprise, before implanting the protons through the second surface into the semiconductor body, forming semiconductor device elements by processing the semiconductor body at the first surface. Structural features of the semiconductor device elements depend on the specific semiconductor device that is formed. For example, the semiconductor device elements may include doped regions, e.g. source region(s), body region(s), current spread region(s), shielding region(s), anode region(s), trench gate electrode structure(s), planar gate electrode structure(s). The semiconductor device elements may also include a wiring area over the first surface. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric may be arranged. Contact plug(s) or contact line(s) may be formed in openings in the interlayer dielectric to electrically connect parts, e.g. metal lines or contact areas, of different wiring levels to one another.

For example, a penetration depth of the protons may be set smaller than a penetration depth of the ions of a non-doping element having an atomic number of at least 9. For example, a penetration depth of the protons may set at least 5%, or at least 10% smaller than a penetration depth of the ions. This may allow for widening a doping profile of a region defined by hydrogen-related donors, e.g. a field stop profile, in depth and, on the other hand, it may prevent the hydrogen from diffusing into a drift region of the semiconductor device. This may be particularly advantageous if interaction of the hydrogen with other elements in the drift region cannot be ruled out. For example, undesirable leakage current-effective Pt-H complex formation may be reduced or suppressed.

For example, a penetration depth of the protons may be set larger than a penetration depth of the ions of a non-doping element having an atomic number of at least 9. For example, a penetration depth of the protons may be set at least 5%, or at least 10% larger than a penetration depth of the ions of a non-doping element having an atomic number of at least 9. Setting a penetration depth of the protons larger than a penetration depth of the ions of a non-doping element having an atomic number of at least 9 may allow for preventing the hydrogen from diffusing out of the semiconductor body, e.g. silicon substrate, during the thermal processing.

For example, a ratio between a penetration depth of the ions of a non-doping element having an atomic number of at least 9 and a penetration depth of the protons may range from 0.1 to 3, or from 0.5 to 2.

For example, a penetration depth of the protons may be set substantially equal to a penetration depth of the ions of a non-doping element having an atomic number of at least 9. Substantially equal may allow for a deviation of the two penetration depths by at most +/−10%, or at most +/−5%, or at most +/−3%, or even smaller. This may allow for further increasing the doping efficiency of the proton irradiation.

For example, implanting the ions of a non-doping element having an atomic number of at least 9 through the second surface into the semiconductor body may include implanting the ions based on at least two different ion implantation energies. This may allow for increasing flexibility in setting the penetration depth of the ions relative to the penetration depth of the protons, and thus allows for combining the benefits described above.

For example, implanting the ions through the second surface into the semiconductor body may include implanting the ions based on at least two different ion implantation tilt angles.

For example, implanting the protons through the second surface into the semiconductor body may include implanting the protons based on at least two different proton implantation tilt angles.

For example, at least part of the ions of a non-doping element having an atomic number of at least 9 may be implanted along a beam axis that deviates by at most 1.5°, or by at most 1.0° from a main crystal axis of the semiconductor body along which channeling occurs. For example, a maximum tilt angle between a main beam direction and the main crystal direction along which channeling of ions occurs as well as an implant beam incidence angle variability of at most ±0.5 degree may be valid for at least 80% of the surface of the semiconductor body. The semiconductor body may have a crystal lattice suitable for channeling ions. Typically, in some crystal directions of single-crystalline materials open spaces extend straight into the crystal. The open spaces form channels through which ions travel with less interaction with the atoms of the crystal lattice than outside the channels. The channels govern the motion of the ions, wherein the ions entering such channels show a deceleration pattern that differs from the deceleration pattern for ions entering the semiconductor body outside the channels. The channel directions coincide with main crystal directions. By implanting the ions at least partly along channeling directions, a broadening of the vacancy concentration profile caused by the interaction of the ions with the lattice of the semiconductor body may be achieved.

For example, the protons may be implanted through the second surface into the semiconductor body before the ions of a non-doping element having an atomic number of at least 9 are implanted through the second surface into the semiconductor body. This may allow for implanting the protons at least partly by a channeled proton implantation which may allow for more flexibility in profile shaping of hydrogen-related donor profiles. For example, the semiconductor body may have a diamond cubic crystal lattice like silicon (Si). In case of a diamond cubic crystal lattice, a surface of the semiconductor body may coincide with a (100) crystal face, may be tilted to the {100} crystal face by at most ±2 degree or may be any other face suitable for channeling. Accordingly, a <100>crystal direction, which is one of several main crystal directions along which channeling occurs, or any other suitable direction, runs perpendicular to the process surface.

For example, the protons may be implanted through the second surface into the semiconductor body after the ions of a non-doping element having an atomic number of at least 9 are implanted through the second surface into the semiconductor body. This may allow for eliminating particles resting on the second surface of the semiconductor body by irradiation with the ions of a non-doping element having an atomic number of at least 9. Thus, the particles may no longer interfere with the homogeneity of the doping profile of the region defined by the hydrogen-related donors, thus also allowing for a reduction in the minimum penetration depth of this region, e.g. field stop region, which is desirable for achieving a beneficial short-circuit resistance of IGBTs, for example. The protons may not be suited to remove the particles, because the energy transferred to the particles may be insufficient to remove the unwanted particles. Moreover, local channeling of the proton implantation may be avoided.

For example, the ions may be implanted into the semiconductor body through openings in an implantation mask, e.g. a resist mask, or a hard mask such as, for example, a low temperature oxide, LTO. This may allow for realizing a lateral variation of a dose of doping, e.g. a lateral variation of hydrogen-related-donors. This may, for example, allow for further benefits to concepts based on achieving, by means of, for example, a field stop that has a lateral variation of the field stop dose, a lateral variation of the carrier flooding by a lateral variation of the partial transistor gain factor, or also a lateral variation of the field distribution. For example, this may be used to realize functions such as high dynamic robustness, HDR (higher field stop dose in the edge region), or Local enhanced backside emitter, LEBE (by an increased flooding with free charge carriers locally in the cell field).

Functional and structural details described with respect to the examples above shall likewise apply to another example of a method of manufacturing a semiconductor device in a semiconductor body having a first surface and a second surface. The method may include introducing hydrogen through the second surface into the semiconductor body. The method may further include implanting ions through the second surface into the semiconductor body. The ions are ions of a non-doping element having an atomic number of at least 9. Thereafter, the method may further include processing the semiconductor body by thermal annealing. As an alternative or in addition to the examples described above, hydrogen may be introduced into the semiconductor body by a process other than ion implantation. For example, hydrogen may be accumulated at or over the second surface by one or more hydrogen plasma treatment, HPT processes, or by a hydrofluoric, HF treatment of the second surface, or by any other process that allows for accumulating hydrogen at or over the second surface. The thermal processing may allow for diffusing and activating hydrogen-related donors in a region where the implanted ions of a non-doping element having an atomic number of at least 9 generated vacancies.

Functional and structural details described with respect to the examples above shall likewise apply to another example of a semiconductor device in a semiconductor body having a first surface and a second surface. The semiconductor device may include an n-doped region defined by hydrogen-related donors in a silicon semiconductor body. The semiconductor device may further include non-doping elements having an atomic number of at least 9. A vertical distance between a peak in a vertical charge carrier concentration profile in the n-doped region and a peak in a vertical concentration profile of the non-doping elements may be smaller than 50% of a vertical distance between the peak in the vertical concentration profile of the non-doping elements and a closest surface of the silicon semiconductor body. The closest surface may be a rear or back surface of the semiconductor device, for example. A front or top surface of the semiconductor device is located opposite to the rear surface. A wiring area including one or more wiring levels, e.g. metal layers may be formed over the front surface of the semiconductor body.

The semiconductor device may further include a drift region. For example, an impurity concentration in the drift region may gradually or in steps increase or decrease with increasing distance to the first main surface at least in portions of its vertical extension. According to other examples the impurity concentration in the drift region may be approximately uniform. For IGBTs based on silicon, a mean impurity concentration in the drift region may be between 5×10¹² cm⁻³ and 1×10¹⁵ cm⁻³, for example in a range from 1×10¹³ cm⁻³ to 2×10¹⁴ cm⁻³. In the case of a semiconductor device based on SiC, a mean impurity concentration in the drift region may be between 5×10¹⁴ cm⁻³ and 1×10¹⁷ cm⁻³, for example in a range from 1×10¹⁵ cm⁻³ to 2×10¹⁶ cm⁻³. A vertical extension of the drift region may depend on voltage blocking requirements, e.g. a specified voltage class, of the semiconductor device. When operating the vertical power semiconductor device in voltage blocking mode, a space charge region may vertically extend partly or totally through the drift region depending on the blocking voltage applied to the vertical power semiconductor device. When operating the vertical power semiconductor device at or close to the specified maximum blocking voltage, the space charge region may reach or penetrate into a field stop region. For example, the drift region may be arranged between the n-doped region defined by the hydrogen-related donors and the front surface.

For example, a dose of the non-doping elements having an atomic number of at least 9 may be smaller than 10¹³cm⁻². This may allow for avoiding generation of higher-order defect complexes that may not be annihilated by the thermal processing described above and thus could undesirably lower the minority carrier lifetime.

For example, a maximum charge carrier concentration in the n-doped region defined by the hydrogen-related donors may range between 3×10¹⁵cm⁻³ and 2×10¹⁷cm⁻³, or between 2×10¹⁶cm⁻³ and 1×10¹⁷cm⁻³, or between 3×10¹⁶ cm⁻³ and 8×10¹⁶ cm⁻³. Since vacancy generation caused by implanting the non-doping elements having an atomic number of at least 9 may be larger than for lighter for ions such as, for example, protons or helium ions, larger maximum charge carrier concentrations in the n-doped region defined by the hydrogen-related donors may be achieved.

For example, a charge carrier concentration profile in the n-doped region may have a plurality of local minima along a lateral direction.

For example, the n-doped region may be a field stop region. The field stop region may be configured to prevent the space charge region from further reaching to the cathode or collector at the second surface, e.g. rear surface, of the semiconductor body. In this manner, the drift or base region may be formed using desired low doping levels and with a desired thickness while achieving soft switching for the semiconductor device thus formed. Since the field stop region aims at preventing the space charge region from reaching the cathode or collector at the second main surface of the semiconductor body in a voltage blocking mode at or around maximum specified voltage blocking capabilities of the semiconductor device, a mean net impurity concentration in the field stop layer may be higher than in the drift region by at least one order of magnitude, for example. Moreover, the mean net impurity concentration in the field stop layer may be lower than the impurity concentration in a cathode contact layer or collector contact layer by at least one order of magnitude, for example. For example, the field stop region may include one, two, three or even more concentration peaks of hydrogen-related donors. This may be achieved by a corresponding number of proton implantations having different proton implantation energies, for example.

More details and aspects are mentioned in connection with the examples described above or below. Processing the semiconductor body may comprise one or more optional additional features corresponding to one or more aspects mentioned in connection with the proposed concept or one or more examples described above or below.

The aspects and features mentioned and described together with one or more of the previously described examples and figures may as well be combined with one or more of the other examples in order to replace a like feature of the other example or in order to additionally introduce the feature to the other example.

It will be appreciated that while the method is described above and below as a series of steps or events, the described ordering of such steps or events are not to be interpreted in a limiting sense. Rather, some steps may occur in different orders and/or concurrently with other steps or events apart from those described above and below.

Functional and structural details described with respect to the examples above shall likewise apply to the examples illustrated in the figures and described further below.

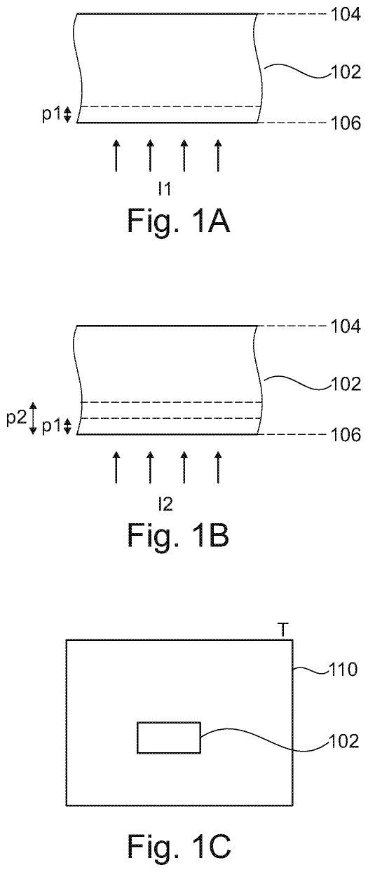

Referring to the schematic cross-sectional views of FIGS. 1A to 10, exemplary process features for manufacturing a semiconductor device in a semiconductor body 102 having a first surface 104 and a second surface 106 are illustrated.

Referring to FIG. 1A, protons are implanted (see arrows marked I1) through the second surface 106 into the semiconductor body 102 up to a penetration depth p1.

Referring to FIG. 1B, ions of a non-doping element having an atomic number of at least 9 are implanted (see arrows marked I2) through the second surface 106 into the semiconductor body 102 up to a penetration depth p2. As illustrated in FIG. 1B, the penetration depth p2 may be larger than the penetration depth p1. However, the penetration depth p2 may also be smaller or substantially equal than the penetration depth p1. As is illustrated in FIGS. 1A, 1B, the protons may be implanted before implanting the ions having an atomic number of at least 9. However, the protons may also be implanted after implanting the ions having an atomic number of at least 9.

Referring to FIG. 10, the semiconductor body is processed by thermal annealing in a thermal processing equipment 110, e.g. a furnace. This may allow for activating hydrogen-related donors, for example.

Referring to the schematic cross-sectional view of FIG. 2, front side processing of the semiconductor body 102 is carried out. In view of the vast variety of semiconductor devices that may be formed, front side processing of the semiconductor body 102 is simplified by a resulting front side structure 112. Structural features of the front side structure 112 depend on the specific semiconductor device that is formed. For example, a first front side structure portion 1121 may include semiconductor device elements such as doped regions, e.g. source region(s), body region(s), current spread region(s), shielding region(s), anode region(s), trench gate electrode structure(s). The front side structure 112 may also include a second front side structure portion 1122. The second front side structure portion 1122 may be, or may include a wiring area over the semiconductor body 102. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric may be arranged. Contact plug(s) or contact line(s) may be formed in openings in the interlayer dielectric to electrically connect parts, e.g. metal lines or contact areas, of different wiring levels to one another.

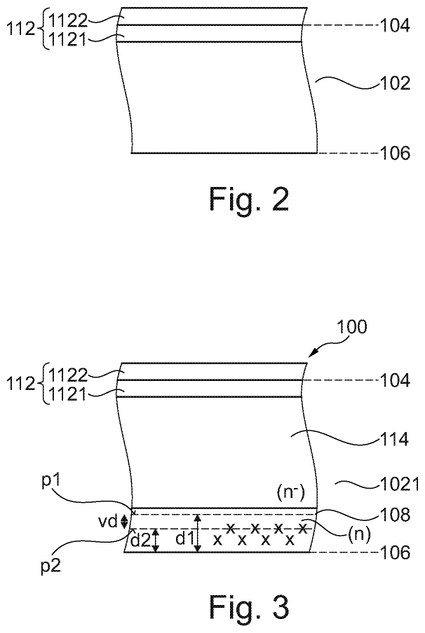

An example of a semiconductor device 100 that may be manufactured by the method illustrated in FIGS. 1A to 2 is illustrated in the schematic cross-sectional view of FIG. 3. The semiconductor device includes the front side structure 112 at the first surface 104. The semiconductor device 100 further includes an n-doped region 108, e.g. a field stop region, defined by hydrogen-related donors in a silicon semiconductor body 1021. The semiconductor device 100 further includes an n⁻-doped drift region arranged between the n-doped region 108 and the front side structure 112. The semiconductor device 100 further includes non-doping elements having an atomic number of at least 9 (schematically illustrated by crosses x). A vertical distance vd between a peak P1 in a vertical charge carrier concentration profile in the n-doped region 108 and a peak P2 in a vertical concentration profile of the non-doping elements is smaller than 50% of a vertical distance d2 between the peak P2 in the vertical concentration profile of the non-doping elements and a second surface 106 of the silicon semiconductor body 1021.

For example, the semiconductor device 100 may be a vertical power semiconductor diode, or a vertical power insulated gate field effect transistor (power IGFETs) such as metal oxide semiconductor field effect transistor (MOSFET) or a vertical power insulated gate bipolar transistor (power IGBT).

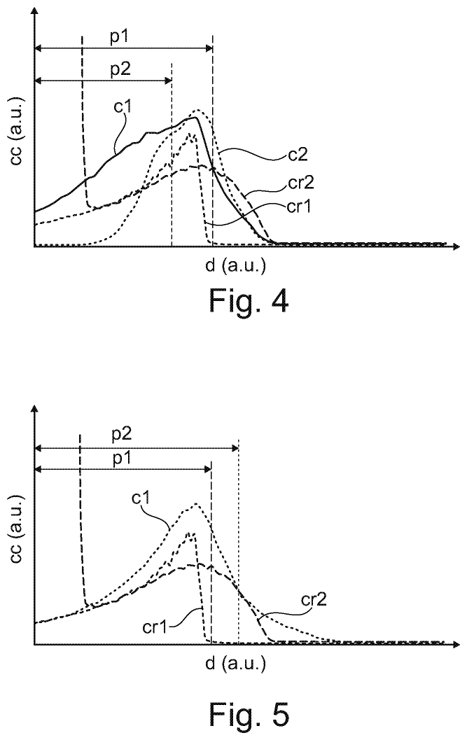

The schematic graph of FIG. 4 illustrates experimental results of carrier concentrations cc (determined by spreading resistance profiling, SRP, or by secondary ion mass spectrometry, SIMS) of an n-doped region defined by hydrogen-related donors versus a depth d to the closest surface of the semiconductor body. In the schematic graph of FIG. 4, the proton penetration depth p1 is larger than the penetration depth p2 of non-doping ions, e.g. argon ions. The concentration profiles c1, c2 refer to n-doped regions defined by hydrogen-related donors that are based on argon implantations of different dose, wherein the dose and energy of the proton implantations are the same. Reference concentration profiles cr1, cr2 are based on proton implantations without any argon implantation, wherein the proton implantation dose of all concentration profiles c1, c2, cr1, cr2 are the same, the proton implantation energies of c1, c2, cr1 are the same, and the proton implantation energy and the proton implantation tilt angle of cr2 exceeds that one of c1, c2, cr1. The experimental results demonstrate an increase in the doping efficiency of proton irradiation caused by the argon implantation.

Another example based on experimental data is illustrated in the graph of FIG. 5. In the schematic graph of FIG. 5, the proton penetration depth p1 is smaller than the penetration depth p2 of non-doping ions, e.g. argon ions. The concentration profile c3 refers to an n-doped region defined by hydrogen-related donors that is based on argon implantation, wherein the dose and energy of the proton implantation is the same as for the reference concentration profile cr1, and the dose is further the same as for the reference concentration profile cr2. Again, the experimental results demonstrate an increase in the doping efficiency of proton irradiation caused by the argon implantation. Moreover, the concentration profile c3 may be extended deeper into the semiconductor body compared with the profiles c1, c2 in FIG. 4, and diffusion of hydrogen into the drift region may be decreased or suppressed.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing a semiconductor device in a semiconductor body having a first surface and a second surface, the method comprising:
implanting protons through the second surface into the semiconductor body;
implanting ions through the second surface into the semiconductor body, wherein the ions are ions of a non-doping element having an atomic number of at least 9; and
after the implanting of the ions, processing the semiconductor body by thermal annealing.

2. The method of claim 1, wherein the thermal annealing is carried out in a temperature range from 350° C. to 430° C. for a period from 30 minutes to 4 hours.

3. The method of claim 1, wherein the semiconductor body is a silicon semiconductor body and the ions are selected from the group consisting of silicon, argon, krypton, xenon, neon, fluorine, and germanium.

4. The method of claim 1, wherein the ions are implanted at a dose smaller than 10¹³cm⁻².

5. The method of claim 1, further comprising, before the implanting of the protons, forming semiconductor device elements by processing the semiconductor body at the first surface.

6. The method of claim 1, wherein a penetration depth of the protons is set smaller than a penetration depth of the ions.

7. The method of claim 1, wherein a penetration depth of the protons is set larger than a penetration depth of the ions.

8. The method of claim 1, wherein a ratio between a penetration depth of the ions and a penetration depth of the protons ranges from 0.1 to 3.

9. The method of claim 1, wherein a penetration depth of the protons is set substantially equal to a penetration depth of the ions.

10. The method of claim 1, wherein the implanting of the ions comprises implanting the ions based on at least two different ion implantation energies.

11. The method of claim 1, wherein the implanting of the ions comprises implanting the ions based on at least two different ion implantation tilt angles.

12. The method of claim 1, wherein the implanting of the protons comprises implanting the protons based on at least two different proton implantation tilt angles.

13. The method of claim 1, wherein at least some of the ions are implanted along a beam axis that deviates by at most 1.5° from a main crystal axis of the semiconductor body along which channeling occurs.

14. The method of claim 1, wherein the protons are implanted through the second surface into the semiconductor body before the ions are implanted through the second surface into the semiconductor body.

15. The method of claim 1, wherein the protons are implanted through the second surface into the semiconductor body after the ions are implanted through the second surface into the semiconductor body.

16. The method of claim 1, wherein the ions are implanted into the semiconductor body through openings in an implantation mask.

17. A method of manufacturing a semiconductor device in a semiconductor body having a first surface and a second surface, the method comprising:
introducing hydrogen through the second surface into the semiconductor body;
implanting ions through the second surface into the semiconductor body, wherein the ions are ions of a non-doping element having an atomic number of at least 9; and
after the implanting of the ions, processing the semiconductor body by thermal annealing.

18. A semiconductor device, comprising:
an n-doped region defined by hydrogen-related donors in a silicon semiconductor body;
non-doping elements having an atomic number of at least 9,
wherein a vertical distance between a peak in a vertical charge carrier concentration profile in the n-doped region and a peak in a vertical concentration profile of the non-doping elements is smaller than 50% of a vertical distance between the peak in the vertical concentration profile of the non-doping elements and a closest surface of the silicon semiconductor body.

19. The semiconductor device of claim 18, wherein a dose of the non-doping elements is smaller than 10¹³cm⁻².

20. The semiconductor device of claim 18, wherein a maximum charge carrier concentration in the n-doped region defined by the hydrogen-related donors ranges between 3×10¹⁵cm⁻³ and 2×10¹⁷cm⁻³.

21. The semiconductor device of claim 18, wherein a charge carrier concentration profile in the n-doped region has a plurality of local minima along a lateral direction.

22. The semiconductor device of claim 18, wherein the n-doped region is a field stop region.
